(19) United States
(12) Patent Application Publication
(10) Pub. No.: US 2006/0023731 A1
(43) Pub. Date: Feb. 2, 2006

(54) Method and apparatus for processing data in a communication system

(76) Inventor: Eduardo Asbun, Tijuana (MX)

Correspondence Address: MOSER, PATTERSON & SHERIDAN L.L.P., 595 SHREWSBURY AVE, STE 100, FIRST FLOOR, SHREWSBURY, NJ, 07702, US

(21) Appl. No.: 10/901,757

(22) Filed: Jul. 29, 2004

(51) Int. Cl. G01R 31/08; H04J 3/26

(52) U.S. Cl. 370/432; 370/252

(57) ABSTRACT

Method and apparatus for processing data received from a network is described. In one example, a data frame is received from the network. Identification data is obtained from the data frame at a data link layer (e.g., Ethernet layer) to determine whether the data frame is a multicast frame. A checksum value is verified at a network layer (e.g., internet protocol layer) in response to the data frame being a multicast frame. Data is extracted from a payload of a transport layer immediately following verification of the checksum value.

### BACKGROUND OF THE INVENTION

1. Field of the Invention

The present invention relates to data processing systems and, more particularly, to a method and apparatus for processing data frames in a communication system.

2. Description of the Background Art

Historically, network applications rely on an internet protocol (IP) stack for transmitting and receiving data. Each network interface in the network implements an IP stack, which is generally configured to handle processing of both the IP protocol and the various transport protocols that may be used (e.g., user datagram protocol (UDP), transport control protocol (TCP), internet control message protocol (ICMP), internet group management protocol (IGMP)). Network multicasting is one type of communication mechanism whereby data is sent to a group of network interfaces using a common IP address. Notably, class D addresses (224.0.0.0 to 239.255.255.255) identify groups of network interfaces, rather than individual network interfaces. For this reason, class D addresses are also referred to as “multicast groups.” A datagram with a class D destination address is delivered to every network interface in the network that has joined the corresponding multicast group.

The term “datagram” refers to a data unit comprising an IP header and a message that includes a transport header (e.g., UDP header) and application data. As is well known in the art, if a datagram is too large for transmission over the selected network (e.g., Ethernet network), the IP stack divides the datagram into fragments, each of which contains its own IP header and a portion of the original datagram. The datagrams are encapsulated by data frames in accordance with the type of network used for transmission (e.g., Ethernet frames).

FIG. 5 is a flow diagram depicting a conventional process 500 performed by an IP stack for processing an IP datagram. The process 500 is performed at both an IP layer and a transport layer (UDP layer in the present example). In the IP layer, at step 504, an IP datagram is received. At step 506, the header of the IP datagram is verified. IP header processing involves verification of IP version, IP header length, IP checksum, byte ordering, and packet length parameters. At step 508, IP options are processed. At step 510, the correct destination/forwarding address for the IP datagram is verified. At step 512, the IP packet is passed to a packet defragmentation process. At step 514, the message is passed to the appropriate transport protocol process (e.g., UDP layer). In the UDP layer, at step 516, the UDP checksum is verified. At step 518, a destination application for the datagram is determined.

In some applications, such as real-time control of video encoders, a central network element (e.g., transport stream processor) is required to periodically process bursts of IP datagrams from a multiplicity of source network elements (i.e., encoders) at a high frequency. Processing each received IP datagram using a conventional IP stack becomes a bottleneck that limits performance of the system. Accordingly, there exists a need in the art for efficient processing of data in a communication system.

### SUMMARY OF THE INVENTION

One aspect of the invention relates to a method and apparatus for processing data received from a network. In one embodiment, a data frame is received from the network. Identification data is obtained from the data frame at a data link layer (e.g., Ethernet layer) to determine whether the data frame is a multicast frame. A checksum value is verified at a network layer (e.g., internet protocol layer) in response to the data frame being a multicast frame. Data is extracted from a payload of a transport layer immediately following verification of the checksum value.

Another aspect of the invention relates to communication between a plurality of video encoders and a transport stream processor. First multicast frames are transmitted into a network from a plurality of video encoders. The first multicast frames include statistical data. Data frames are received from the network at a transport stream processor. Identification data is obtained from each of the data frames at a data link layer to identify the first multicast frames. A checksum value is verified at a network layer for each of the multicast frames. Data is extracted from a payload of a transport layer immediately following verification of the checksum value for each of the first multicast frames. Second multicast frames may then be transmitted into the network from the transport stream processor. Each of the second multicast frames includes bit-rate allocation data for the plurality of video encoders.

### BRIEF DESCRIPTION OF DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a block diagram depicting an exemplary embodiment of a video distribution system in which the present invention may be employed;

FIG. 2 is a block diagram depicting an exemplary embodiment of a transport stream processor constructed in accordance with the invention;

FIG. 3 is a flow diagram depicting an exemplary embodiment of a method for controlling a video distribution system in accordance with the invention;

FIG. 4 is a flow diagram depicting an exemplary embodiment of a method for processing data frames in a communication system in accordance with the invention; and

FIG. 5 is a flow diagram depicting a conventional process performed by an IP stack for processing an IP datagram.

To facilitate understanding, identical reference numerals have been used, where possible, to designate identical elements that are common to the figures.

### DETAILED DESCRIPTION OF THE INVENTION

Method and apparatus for processing data frames in a communication system is described. One or more aspects of the invention relate to processing data frames communicated between a plurality of video encoders and a transport stream processor in a video distribution system. However, those skilled in the art will appreciate that the invention may be employed to process data frames in other types of network communication systems.

FIG. 1 is a block diagram depicting an exemplary embodiment of a video distribution system 100 in which the present invention may be employed. The video distribution system 100 comprises a transport stream processor (“transport stream multiplexer (TMX) 102”), a network 106, a control system 108, and encoders 104₁ through 104_{N} (collectively referred to as encoders 104), where N is an integer greater than zero. The video distribution system 100 is configured for statistical coding and multiplexing of multiple video programs to produce one or more multiplexed bitstreams (e.g., one or more transport streams). The video distribution system 100 evaluates statistical information of the video programs being encoded and allocates bits for coding the different video programs in order to maintain a total bit-rate of the multiplexed streams and a satisfactory video quality for each video program. The statistical multiplexing process is controlled via communication between the encoders 104 and the TMX 102 over the network 106.

In particular, an input port of each of the encoders 104 is configured to receive uncompressed source video content for a particular video program. Each of the encoders 104 may comprise a conventional video encoder. Notably, the encoders 104 compress the source video content using a video coding technique. The encoders 104 may employ various video coding techniques that comply with well known standards developed by the Motion Picture Experts Group (MPEG) and International Telecommunications Union (ITU-T), such as MPEG-1, MPEG-2, MPEG-4, ITU-T H261, and ITU-T H263 standards. For purposes of clarity by example, the encoders 104 are described herein as employing an MPEG-2 video coding technique, although other video coding techniques may be employed.

Input ports 105₁ through 105_{N} of the TMX 102 (collectively referred to as input ports 105) are configured to receive encoded video content from the encoders 104₁ through 104_{N}, respectively. The input ports 105 may comprise asynchronous serial interface (ASI) ports, for example. The TMX 102 produces one or more multiplexed bitstreams from the encoded content (e.g., one or more transport streams). A control port of the TMX 102 is coupled to the network 106. Likewise, a control port of each encoder 104 is also coupled to the network 106. The network 106 may comprise a local area network (LAN), such as an Ethernet network (e.g., 10BaseT, 100BaseT, or Gigabit), a Token Ring network, and like-type LANs known in the art. For purposes of clarity by example, the network 106 is described as being an Ethernet network. General configuration of the TMX 102 and the encoders 104 may be performed by the control system 108 through the network 106. The control system 108 may comprise a conventional element management system.

Control information for statistical multiplexing is communicated between the TMX 102 and each of the encoders 104 using a UDP/IP (user datagram protocol/internet protocol) communication protocol. In particular, each of the encoders 104 sends statistical information to the TMX 102 via a multicast address, and the TMX 102 sends bit-rate allocation data to the encoders 104 via another multicast address. For each of the encoders 104, the statistical information typically comprises a need parameter and encoder settings (e.g., the actual bit-rate of the encoded video program). Transmission of statistical information to the TMX 102 and return of bit-rate allocation data to the encoders 104 is referred to herein as a “message cycle”. The message cycles are performed periodically at predefined intervals.

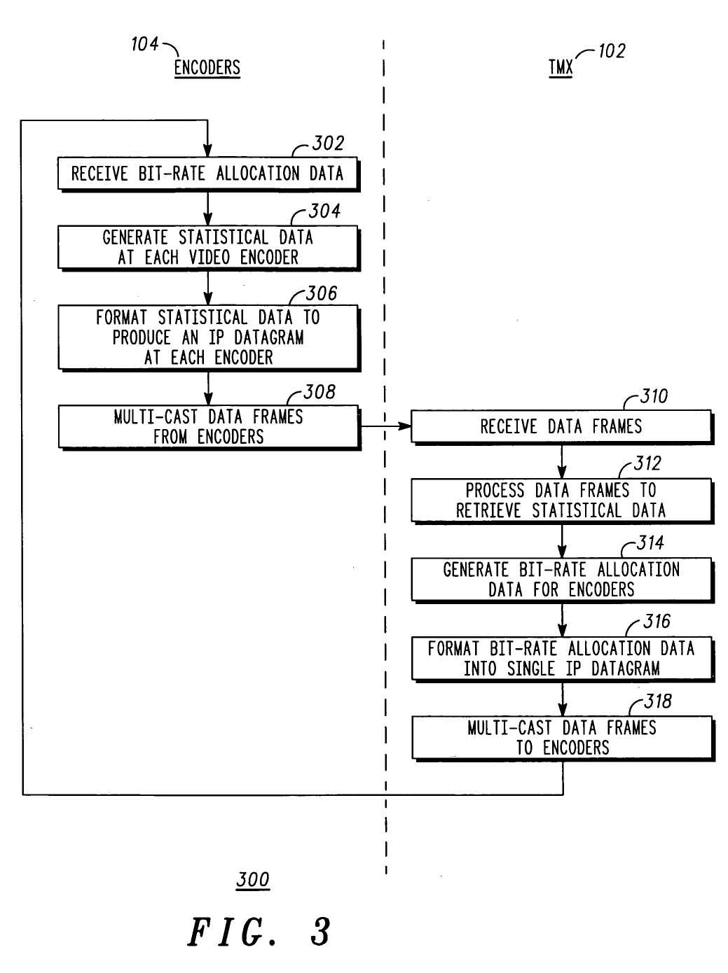

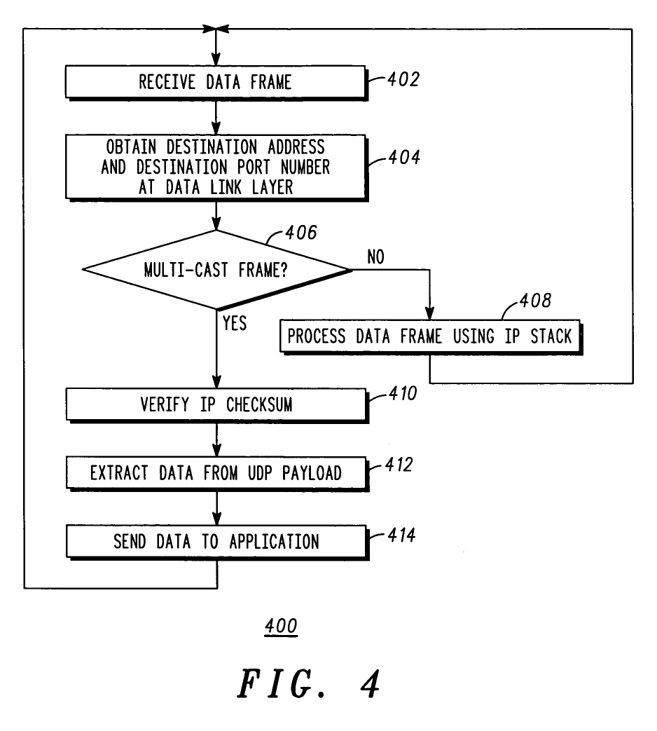

The amount of control traffic between the TMX 102 and the encoders 104 depends on the period of the message cycle. For example, if the message cycle period is 848 microseconds and there are 30 encoders 104, the TMX 102 sends 1,179 messages per second to the encoders 104, and the TMX receives 35,370 messages per second (i.e., 30*1,179) from the encoders 104. In accordance with the invention, for each message cycle, the statistical information generated by each of the encoders 104 is multicasted to the TMX 102, and the bit-rate allocation data computed by the TMX 102 is combined into a single message and multicasted to the encoders 104. By multicasting a single bit-rate allocation message to the encoders 104, protocol overhead is reduced. In addition, as described below, the TMX 102 bypasses the IP stack when processing multicast traffic from the encoders 104. In this manner, the TMX 102 avoids performing unnecessary operations and speeds up the processing of the statistical information to produce the bit-rate allocation data. Operation of the video distribution system 100 for each message cycle may be more thoroughly understood with reference to FIGS. 3 and 4 described below.

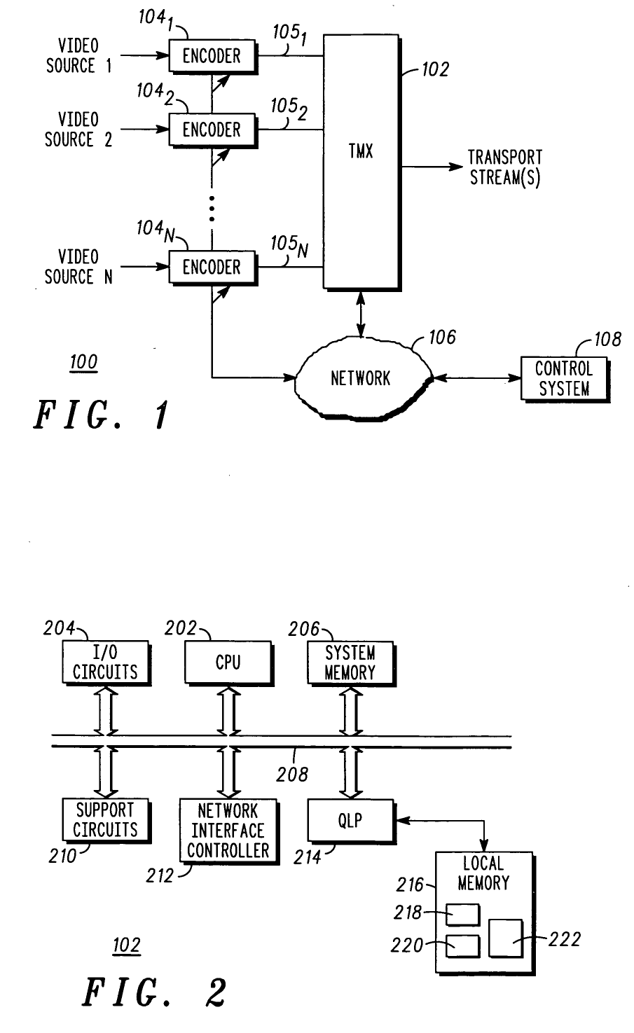

FIG. 2 is a block diagram depicting an exemplary embodiment of the TMX 102 constructed in accordance with the invention. The TMX 102 comprises bus circuitry 208 coupled to each of a central processing unit (CPU) 202, input/output (I/O) circuits 204, system memory 206, various support circuits 210, a network interface controller (NIC) 212, and a quantization level processor (QLP) 214. The CPU 202 may be any type of microprocessor known in the art (e.g., a PowerPC processor). The support circuits 210 include conventional cache, power supplies, clock circuits, data registers, I/O interfaces, and the like. The I/O circuits 204 comprise conventional circuits for communicating data to and from the TMX 102 (e.g., ASI circuits, network circuits, and the like). The system memory 206 may include one or more of random access memory (RAM), read only memory (ROM), magneto-resistive read/write memory, optical read/write memory, cache memory, magnetic read/write memory, and the like.

The QLP 214 is configured to compute bit-rate allocation data for the encoders 104. Statistical information is received from the encoders 104, and the bit-rate allocation is sent to the encoders 104, directly through the NIC 212 without participation by the CPU 202. In this manner, the CPU 202 avoids having to process communications between the QLP 214 and the encoders 104 for every message cycle, which allows the CPU 202 to perform other tasks. The NIC 212 is programmed and controlled by the QLP 214. The QLP 214 may be configured for communication with a local memory 216. The local memory 216 may store data frames received from video encoders (“receive data frames 218”) and data frames configured to transmission to the video encoders (“transmit data frames 220”). The local memory 216 may also store software 222 for execution by the QLP 214 to perform processes and methods described herein.

FIG. 3 is a flow diagram depicting an exemplary embodiment of a method 300 for controlling a video distribution system in accordance with the invention. The method 300 may be understood with simultaneous reference to the video distribution system 100 of FIG. 1. The method 300 is performed by both the encoders 104 and the TMX 102. At step 302, bit-rate allocation data is received at the encoders 104 from the TMX 102. At step 304, statistical data is generated at each of the encoders 104. At step 306, the statistical data is formatted to produce an IP datagram at each of the encoders 104. At step 308, a data frame containing the IP datagram is multicasted to the TMX 102 from each of the encoders 104 (e.g., an Ethernet frame). As described below, general IP stack processing is bypassed in the TMX 102 when the multicast frames from the encoders 104 are processed. Notably, steps of IP options processing and packet defragmentation are not performed. Thus, in one embodiment, when the statistical data is formatted at step 304, IP options are not used and packet fragmentation is not performed (i.e., the statistical data for a given encoder is formatted into a single message).

At step 310, data frames are received at the TMX 102 from the network 106. At step 312, the data frames are processed to retrieve statistical data. An exemplary embodiment of such a process is described below with respect to FIG. 4. At step 314, bit-rate allocation data is generated for the encoders 104 for the next message cycle. At step 316, the bit-rate allocation data is formatted into a single IP datagram. At step 318, data frames containing the IP datagram are multicasted to the encoders 104. The process 300 may then be repeated for each message cycle.

FIG. 4 is a flow diagram depicting an exemplary embodiment of a method 400 for processing data frames in a communication system in accordance with the invention. The method 400 may be performed by the QLP 214 of the TMX 102 of FIGS. 1 and 2 during step 312 of the method 300 of FIG. 3. In one embodiment, the process 400 may be implemented as software for execution by the QLP 214. The method 400 begins at step 402, where a data frame is received from a network. The data frame is formatted in accordance with the data link protocol of the network (e.g., Ethernet frames). At step 404, a destination IP address and a destination port number are obtained at the data link layer (e.g., Ethernet layer). In general, identification data is obtained at step 404, which may comprise a destination IP address, or both a destination IP address and a destination port number.

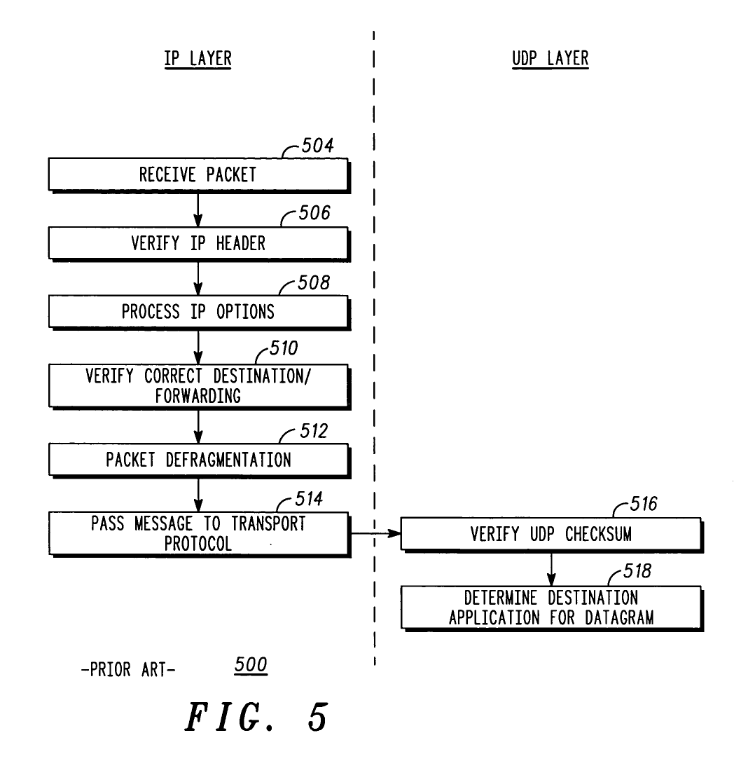

At step 406, a determination is made as to whether the data frame is a multicast frame. Notably, if the destination IP address is a multicast address, the data frame may be deemed to be a multicast frame. In addition, the destination port number may be analyzed to determine the destination application of a multicast frame. The destination port number may be used to cull out multicast frames that are not associated with a particular application being executed by the QLP 214. If the data frame is not a multicast frame (or an undesired multicast frame based on destination port number), the method 400 proceeds to step 408. At step 408, the data frame is processed using a conventional IP stack process, such as that described above with respect to FIG. 5.

If at step 406 the data frame is a multicast frame (or a desired multicast frame based on destination port number), the method 400 proceeds to step 410. At step 410, the IP header is processed to verify the IP checksum value. At step 412, data is extracted from the UDP payload. While UDP/IP is specifically described, it is to be understood that, in general, a checksum value is verified at the network layer and data is extracted from a payload at the transport layer. At step 314, the extracted data is sent to the application being executed by the QLP 214 (“application layer”). The process 400 may be repeated for each received data frame.

Notably, if the received data frame comprises a desired multicast frame, the invention bypasses general processing of the multicast frame by the IP stack (step 408). Instead, data is extracted from a payload at the transport layer directly from the checksum verified multicast frames. That is, the steps of IP options processing, destination/forwarding address verification, and defragmentation are not performed with respect to the data frame between the steps of checksum verification and data extraction. In addition, only the IP checksum is verified during IP header processing. The steps of version verification, header length verification, byte ordering verification, and packet length verification during IP header processing are not performed. Moreover, the transport layer checksum verification is also not performed. The integrity of the data frame may be checked by the network interface controller upon receipt (e.g., a cyclic redundancy check (CRC)). In this manner, the invention advantageously increases performance when processing multicast frames. In particular, performance of the control mechanism of the video distribution system 100 is greatly increased, given the large amount of multicast traffic between the TMX 102 and the encoders 104.

While the foregoing is directed to illustrative embodiments of the present invention, other and further embodiments of the invention may be devised without departing from the basic scope thereof, and the scope thereof is determined by the claims that follow.

What is claimed is:

1. A method of processing data received from a network, comprising:
receiving a data frame from said network;
obtaining identification data from said data frame at a data link layer to determine whether said data frame is a multicast frame;
verifying a checksum value at a network layer in response to said data frame being a multicast frame to produce a verified data frame; and
extracting data from a payload of a transport layer directly from said verified data frame.

2. The method of claim 1, wherein said data is extracted from said payload without performing steps of network layer options processing, destination/forwarding address verification, and defragmentation after said checksum value is verified.

3. The method of claim 2, wherein said data is extracted from said payload without version verification, header length verification, byte ordering verification, and packet length verification after said checksum value is verified.

4. The method of claim 2, wherein said data is extracted from said payload without transport layer checksum verification after said checksum value is verified.

5. The method of claim 1, wherein said identification data comprises a destination address defined in accordance with said network layer.

6. The method of claim 5, wherein said identification data further comprises a destination port number associated an application.

7. The method of claim 1, further comprising:
repeating said steps of receiving, obtaining, verifying, and extracting for one or more additional data frames.

8. The method of claim 1, wherein said data frame comprises an Ethernet frame, and wherein said data link layer comprises an Ethernet layer.

9. The method of claim 1, wherein said network layer comprises an internet protocol layer and said transport layer comprises a user datagram protocol layer.

10. The method of claim 1, further comprising:
providing said extracted data to an application layer.

11. A method of communication between a plurality of video encoders and a transport stream processor, comprising:
transmitting first multicast frames into a network from said plurality of video encoders, said first multicast frames including statistical data;
receiving data frames from said network at said transport stream processor;
obtaining identification data from each of said data frames at a data link layer to identify said first multicast frames;
verifying a checksum value at a network layer for each of said first multicast frames to produce verified multicast frames; and
extracting data from a payload of a transport layer directly from each of said verified multicast frames.

12. The method of claim 11, further comprising:
transmitting second multicast frames into said network from said transport stream processor, each of said second multicast frames including bit-rate allocation data for said plurality of video encoders.

13. Apparatus for processing data received from a network, comprising:
a network interface for receiving data frames from said network; and
a processor for obtaining identification data from each of said data frames at a data link layer to identify multicast frames, verifying a checksum value at a network layer for each of said multicast frames to produce verified multicast frames, and extracting data from a payload of a transport layer directly from said verified multicast frames.

14. The apparatus of claim 13, wherein said identification data comprises a destination address defined in accordance with said network layer.

15. The apparatus of claim 14, wherein said identification data further comprises a destination port number.

16. The apparatus of claim 13, wherein said network interface comprises an Ethernet interface, said data frames comprise Ethernet frames, and said data link layer comprises an Ethernet layer.

17. The apparatus of claim 13, wherein said network layer comprises an internet protocol layer and said transport layer comprises a user datagram protocol.

18. The apparatus of claim 13, wherein said processor comprises a quantization level processor and said extracted data comprises parametric data associated with a video encoder.

19. A communication system, comprising:
a data network;
a plurality of source elements for providing multicast frames into said data network;
a destination element in communication with said data network, said destination element including:
a network interface for receiving data frames from said data network; and
a processor for obtaining identification data from each of said data frames at a data link layer to identify said multicast frames, verifying a checksum value at a network layer for each of said multicast frames to produce verified multicast frames, and extracting data from a payload of a transport layer directly from said verified multicast frames.

20. The system of claim 19, wherein each of said plurality of source elements comprises a video encoder, and wherein said destination element comprises a transport stream processor.

21. The system of claim 20, wherein said processor comprises a quantization level processor, and wherein said extracted data comprises parametric data associated with one of said plurality of video encoders.

22. A computer readable carrier including program instructions that instruct a computer to perform a method of:
receiving a data frame from said network;
obtaining identification data from said data frame at a data link layer to determine whether said data frame is a multicast frame;
verifying a checksum value at a network layer in response to said data frame being a multicast frame to produce a verified data frame; and
extracting data from a payload of a transport layer directly from said verified data frame.
